(19) United States
(12) Patent Application Publication
(10) Pub. No.: US 2011/0117481 A1
(43) Pub. Date: May 19, 2011

(54) PELLICLE FOR LITHOGRAPHY

(75) Inventor: Yuichi HAMADA, Gunma (JP)

(73) Assignee: SHIN-ETSU CHEMICAL CO., LTD., Tokyo (JP)

(21) Appl. No.: 12/944,188

(22) Filed: Nov. 11, 2010

(30) Foreign Application Priority Data
Nov. 16, 2009 (JP) 2009-260600

(51) Int. Cl. G03F 1/00

(52) U.S. Cl. 430/5

(57) ABSTRACT

A pellicle for lithography is provided that includes a pellicle frame provided with an atmospheric pressure adjustment hole that extends through from an outer peripheral face to an inner peripheral face, a ratio S/L of a cross-sectional area S (mm²) of a cross-section that is perpendicular to the depth direction of the atmospheric pressure adjustment hole relative to a length L (mm) in the depth direction of the atmospheric pressure adjustment hole being at least 0.25 mm but no greater than 5.0 mm.

### BACKGROUND OF THE INVENTION

1. Field of the Invention

The present invention relates to a pellicle for lithography that is used as a debris shield for a lithographic mask when producing a liquid crystal display panel or a semiconductor device such as an LSI or a ULSI.

2. Description of the Related Art

In the production of a semiconductor such as an LSI or a ULSI or the production of a liquid crystal display panel, patterning is carried out by irradiating a semiconductor wafer or a liquid crystal master plate with light; if debris is attached to an exposure master plate used here, since the debris absorbs the light or bends the light, there are the problems that the replicated pattern is deformed, the edge becomes rough, or the background is stained black, thus impairing the dimensions, quality, appearance, etc. The ‘exposure master plate’ referred to in the present invention is a general term for lithographic masks and reticles.

These operations are usually carried out in a clean room, but even within a clean room it is difficult to always keep the exposure master plate clean, and a method is therefore employed in which a pellicle that allows exposure light to easily pass through is adhered to the surface of the exposure master plate to act as a debris shield.

In this case, the debris does not become attached directly to the surface of the exposure master plate but becomes attached to the pellicle film, and by focusing on a pattern of the exposure master plate when carrying out lithography the debris on the pellicle film does not become involved in the replication.

A pellicle is basically constituted from a pellicle frame and a pellicle film stretched over the frame. The pellicle film is formed from nitrocellulose, cellulose acetate, a fluorine-based polymer, etc., which allows exposure light (g rays, i rays, 248 nm, 193 nm, 157 nm, etc.) to easily pass through. The pellicle frame is formed from a black-anodized etc. A7075, A6061, A5052, etc. aluminum alloy, stainless steel, polyethylene, etc. The pellicle film is adhered by coating the upper part of the pellicle frame with a good solvent for the pellicle film and air-drying (ref. JP-A-58-219023 (JP-A denotes a Japanese unexamined patent application publication)) or by means of an adhesive such as an acrylic resin, an epoxy resin, or a fluorine resin (ref. U.S. Pat. No. 4,861,402, JP-B-63-27707 (JP-B denotes a Japanese examined patent application publication), and Japanese registered patent No. 3089153). Furthermore, since an exposure master plate is mounted on a lower part of the pellicle frame, a pressure-sensitive adhesion layer made of a polybutene resin, a polyvinyl acetate resin, an acrylic resin, a silicone resin, etc. and a reticle pressure-sensitive adhesive protecting liner for the purpose of protecting the pressure-sensitive adhesion layer are provided.

The pellicle is installed so as to surround a pattern region formed on the surface of the exposure master plate. Since the pellicle is provided in order to prevent debris from becoming attached to the exposure master plate, this pattern region and a pellicle outer part are separated so that dust from the pellicle outer part does not become attached to the pattern face.

The present applicant has disclosed a filter-equipped pellicle in which a filter that is to be provided on an atmospheric pressure adjustment hole is wetted with a pressure-sensitive adhesive (ref. JP-A-9-68792).

In particular, since the pellicle is used by affixing it directly to an exposure master plate, there is a desire for a low gas generation rate for materials forming the pellicle, that is, a reticle adhesive, a film adhesive, an inner wall coating agent, etc., which are formed from organic materials, and improvements have been made. Among them, as the reticle adhesive there is one that employs a silicone resin in order to give lower outgassing, improved UV resistance, and improved chemical resistance. Since silicone resins have excellent chemical stability, it is possible to fix a pellicle onto a reticle without there being any changes over a long period of time. However, when the pellicle is to be stripped from the reticle for replacement, it is difficult to carry out stripping well without leaving a residue on the reticle. As a method for stripping a pellicle that has a silicone adhesive, a method in which a substrate from which a pellicle is stripped is heated has been proposed (Patent Publication 1).

In recent years, the LSI design rule has shrunk to sub-quarter micron, and accompanying this the control of foreign matter has become tighter. There is also a demand for flushing with clean air a closed space formed by affixing a pellicle and then carrying out exposure, and the role of the atmospheric pressure adjustment hole of the pellicle frame has become all the more important.

As described in JP-A-9-68792 above, measures against foreign matter with respect to a filter provided on an atmospheric pressure adjustment hole have been proposed, but no measures taken have given a marked improvement for the pellicle frame atmospheric pressure adjustment hole itself.

### BRIEF SUMMARY OF THE INVENTION

The present invention has been accomplished in order to solve the above-mentioned problems. That is, it is an object of the present invention to provide a pellicle for lithography that can reduce foreign matter that either is generated via an atmospheric pressure adjustment hole or might pass therethrough.

The above-mentioned object has been attained by means (1) below. It is described together with (2) to (5), which are preferred embodiments of the present invention.

(1) A pellicle for lithography comprising a pellicle frame provided with an atmospheric pressure adjustment hole that extends through from an outer peripheral face to an inner peripheral face, a ratio S/L of a cross-sectional area S (mm²) of a cross-section that is perpendicular to the depth direction of the atmospheric pressure adjustment hole relative to a length L (mm) in the depth direction of the atmospheric pressure adjustment hole being at least 0.25 mm but no greater than 5.0 mm,

(2) the pellicle for lithography according to (1), wherein the cross-sectional area S is at least 0.5 mm² but no greater than 10.0 mm²,

(3) the pellicle for lithography according to (1), wherein the atmospheric pressure adjustment hole has a diameter of at least 0.8 mm but no greater than 3.6 mm,

(4) the pellicle for lithography according to any one of (1) to (3), wherein the difference between the height of the pellicle frame and the diameter of the atmospheric pressure adjustment hole satisfies the expression below

2mm≦(h−D)≦5mm

(here, h denotes a height (mm) of the pellicle frame and D denotes a diameter (mm) of the atmospheric pressure adjustment hole), and

(5) the pellicle for lithography according to any one of (1) to (4), wherein the atmospheric pressure adjustment hole comprises on its inner wall face an inner wall pressure-sensitive adhesive layer.

### EFFECTS OF THE INVENTION

In accordance with the present invention, by setting the diameter of an atmospheric pressure adjustment hole provided in a pellicle frame at larger than 0.5 mm, which is the diameter of a conventional atmospheric pressure adjustment hole, it is possible to reduce the speed of gas passing therethrough, thereby reducing foreign matter that either is generated via the atmospheric pressure adjustment hole or might pass therethrough.

### BRIEF DESCRIPTION OF THE SEVERAL VIEWS OF THE DRAWINGS

FIG. 1 is an outline perspective view schematically showing the overall constitution of the pellicle for lithography of the present invention.

FIG. 2 is an outline partial enlarged view schematically showing part of a pellicle frame that contains an atmospheric pressure adjustment hole in one embodiment of the pellicle for lithography of the present invention.

### EXPLANATION OF REFERENCE NUMERALS AND SYMBOLS

1: Pellicle film
2: Pellicle film-affixing adhesion layer
3: Pellicle frame
4: Pressure-sensitive adhesion layer
5: Exposure master plate
6: Atmospheric pressure adjustment hole
7: Dust filter
8a, 8b: Inner wall pressure-sensitive adhesive layer
10: Pellicle for lithography

### DETAILED DESCRIPTION OF THE INVENTION

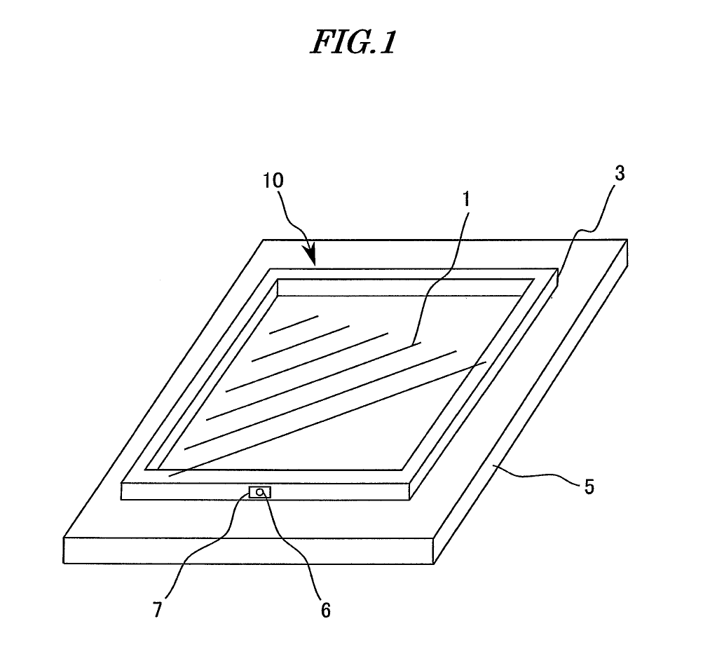

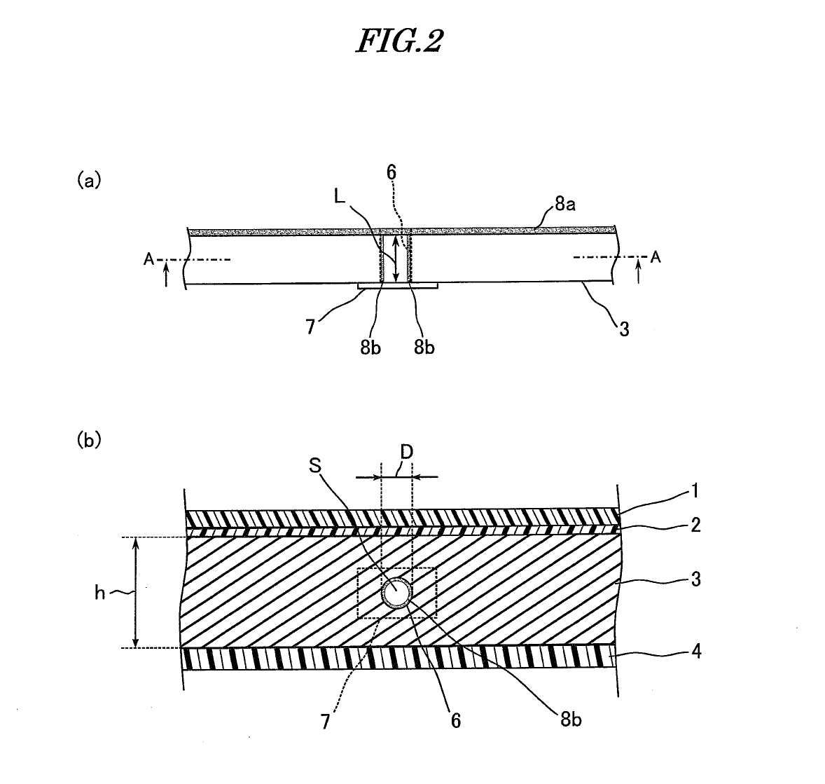

The basic constitution of the pellicle for lithography of the present invention is explained by reference to FIG. 1 and FIG. 2.

FIG. 1 is an outline perspective view schematically showing the overall constitution of the pellicle for lithography of the present invention. FIG. 2 is an outline partial enlarged view schematically showing part of a pellicle frame that contains an atmospheric pressure adjustment hole in one embodiment of the pellicle for lithography of the present invention, FIG. 2 (a) is an outline plan view of the part of the pellicle frame that contains the atmospheric pressure adjustment hole, and FIG. 2 (b) is an outline cross-sectional view along line A-A in FIG. 2 (a).

As shown in FIG. 1 and FIG. 2, the pellicle 10 for lithography of the present invention has a pellicle frame 3, which is for example a substantially rectangular framework body, and a pellicle film 1 stretched over an upper end face of the pellicle frame 3 via a pellicle film-affixing adhesion layer 2.

On a lower end face of the pellicle frame 3, there is formed a pressure-sensitive adhesion layer 4 for adhering the pellicle 10 to an exposure master plate (mask substrate or reticle) 5. A liner (not illustrated) is peelably affixed to a lower end face of the pressure-sensitive adhesion layer 4. This liner is peeled off when the pellicle 10 for lithography is adhered to the exposure master plate 5.

Furthermore, the pellicle frame 3 is provided with an atmospheric pressure adjustment hole (vent) 6 that extends through from its outer peripheral face to its inner peripheral face. On the outer peripheral face of the pellicle frame 3 there is provided, so as to cover an opening of the atmospheric pressure adjustment hole 6, a dust filter 7 for removing foreign matter such as particles.

Furthermore, a resin coating is applied to an inner wall face (an inner peripheral face) of the pellicle frame 3 and an inner wall face of the atmospheric pressure adjustment hole 6 using an inner wall pressure-sensitive adhesive, thus forming inner wall pressure-sensitive adhesive layers 8a and 8b respectively.

The dimensions of these pellicle components are similar to those of a normal pellicle, for example, a pellicle for semiconductor lithography, a pellicle for a lithographic step of large liquid crystal display panel production, etc., and the materials of the components may employ known materials.

The type of pellicle film 1 is not particularly limited and, for example, an amorphous fluorine polymer, etc. that has conventionally been used for an excimer laser is used. Examples of the amorphous fluorine polymer include Cytop (product name, manufactured by Asahi Glass Co. Ltd.) and Teflon (Registered Trademark) AF (product name, manufactured by DuPont). These polymers may be used by dissolving them in a solvent as necessary when preparing the pellicle film, and may be dissolved as appropriate in, for example, a fluorine-based solvent.

As an adhesive used for the pellicle film-affixing adhesion layer 2, one conventionally used may be used, and examples thereof include an acrylic resin adhesive, an epoxy resin adhesive, a silicone resin adhesive, and a fluorine polymer such as a fluorine-containing silicone adhesive and an amorphous fluorine polymer, but for a pellicle film employing an amorphous fluorine polymer, an amorphous fluorine-based polymer is suitable.

With regard to the base material of the pellicle frame 3, a conventionally used aluminum alloy material, and preferably a JIS A7075, JIS A6061, JIS A5052 material, etc., is used, and when an aluminum alloy material is used it is not particularly limited as long as the strength as a pellicle frame is ensured. The surface of the pellicle frame is preferably roughened by sandblasting or chemical abrasion. In the present invention, a method for roughening the surface of the frame may employ a conventionally known method. It is preferable to employ a method for roughening the surface involving blasting the aluminum alloy material surface with stainless steel, carborundum, glass beads, etc., and further by chemically abrading with NaOH, etc.

As the inner wall pressure-sensitive adhesive for forming the inner wall pressure-sensitive adhesive layers 8a and 8b by applying a resin coating to the inner wall face of the pellicle frame 3 and the inner wall face of the atmospheric pressure adjustment hole 6, a silicone pressure-sensitive adhesive and an acrylic pressure-sensitive adhesive may preferably be used, and among them a silicone pressure-sensitive adhesive may more preferably be used.

As an adhesive used for the pressure-sensitive adhesion layer 4 for adhering the pellicle 10 to the exposure master plate 5, various types of adhesive may be selected as appropriate; an acrylic adhesive, a SEBS (poly(styrene-ethylene-butadiene-styrene))-based adhesive, and a silicone-based adhesive may preferably be used, and an acrylic adhesive or a silicone-based adhesive may more preferably be used.

The atmospheric pressure adjustment hole 6 formed in the pellicle frame 3 has, for example, a substantially cylindrical shape having its central axis along the thickness direction from the outer peripheral face toward the inner peripheral face of the pellicle frame 3, and the cross-sectional shape perpendicular to the depth direction is substantially circular.

Furthermore, a ratio S/L of a cross-sectional area S (mm²) of a cross-section that is perpendicular to the depth direction of the atmospheric pressure adjustment hole 6 relative to a length L (mm) in the depth direction of the atmospheric pressure adjustment hole 6 is at least 0.25 mm but no greater than 5.0 mm.

More specifically, a diameter D (mm) of the atmospheric pressure adjustment hole 6 is preferably at least 0.8 mm but no greater than 3.6 mm, and more preferably at least 1.0 mm but no greater than 3.0 mm.

Furthermore, the cross-sectional area S (mm²) of the atmospheric pressure adjustment hole 6 is preferably at least 0.5 mm² but no greater than 10.0 mm², more preferably at least 0.8 mm² but no greater than 8.0 mm², and yet more preferably at least 2.0 mm² but no greater than 5.0 mm².

The diameter D, length L, and cross-sectional area S of the atmospheric pressure adjustment hole 6 are set from the viewpoint of reducing foreign matter that either is generated via the atmospheric pressure adjustment hole 6 or might pass therethrough.

The atmospheric pressure adjustment hole 6 is preferably provided so that the strength required for the pellicle frame 3 is not impaired.

For example, from the viewpoint of ensuring the strength of the pellicle frame 3 and the structure of the filter 7 provided outside the atmospheric pressure adjustment hole 6, it is preferable to set the diameter D of the atmospheric pressure adjustment hole 6 so that a difference (h−D) of a height h (mm) of the pellicle frame 3 and the diameter D (mm) of the atmospheric pressure adjustment hole 6 satisfies Expression (1).

2mm≦(h−D)≦5mm (1)

The atmospheric pressure adjustment hole 6 exhibits the function described below. That is, when the pellicle 10 is affixed to the exposure master plate 5, a closed space is formed between the pellicle 10 and the exposure master plate 5. When the interior of the closed space thus formed by affixing the pellicle 10 is flushed with clean air or an inert gas, the atmospheric pressure adjustment hole 6 takes on an important role such as a role as an inlet or an outlet for clean air. Moreover, when the exposure master plate 5 having the pellicle 10 affixed thereto is transported by air, etc., the atmospheric pressure adjustment hole 6 functions as an opening for relieving a difference in atmospheric pressure occurring between the exterior and the interior of the closed space formed between the pellicle 10 and the exposure master plate 5.

The dust filter 7 provided so as to cover the opening of the atmospheric pressure adjustment hole 6 is not particularly limited in terms of shape, number, or location as long as it is sufficiently permeable for relieving a difference in atmospheric pressure between the interior and the exterior of the pellicle via the atmospheric pressure adjustment hole 6 and it can be provided in the atmospheric pressure adjustment hole 6 area. The material of the dust filter 7 is preferably one that does not generate particulates, and examples thereof include resins (polytetrafluoroethylene (PTFE), nylon 66, etc.), metals (SUS 316L stainless steel, etc.), and ceramics (alumina, aluminum nitride, etc.). It is also preferable for the dust filter 7 to be equipped on its exterior with a chemical filter for adsorbing or decomposing environmental chemical substances.

In FIG. 1 and FIG. 2, a case in which one atmospheric pressure adjustment hole 6 is provided in the pellicle frame 3 is shown, but a plurality of atmospheric pressure adjustment holes 6 may be provided in the pellicle frame 3. Furthermore, in FIG. 1 and FIG. 2, a case in which the atmospheric pressure adjustment hole 6 is provided at substantially the midpoint of a short side of the pellicle frame 3 is shown, but the atmospheric pressure adjustment hole 6 may be provided at any position of a short side or a long side of the pellicle frame 3.

Moreover, in FIG. 1 and FIG. 2, a case in which a cross-sectional shape that is perpendicular to the depth direction of the atmospheric pressure adjustment hole 6 is substantially circular is shown, but the cross-sectional shape of the atmospheric pressure adjustment hole 6 is not limited thereto. The cross-sectional shape of the atmospheric pressure adjustment hole 6 may be, other than a circle, an oval or a polygon such as a triangle, a rectangle, or a pentagon.

The pellicle for lithography of the present invention is mainly characterized in that, as described above, the ratio S/L of the cross-sectional area S (mm²) of a cross-section that is perpendicular to the depth direction of the atmospheric pressure adjustment hole 6 relative to the length L (mm) in the depth direction of the atmospheric pressure adjustment hole 6 is at least 0.25 mm but no greater than 5.0 mm, and the diameter D (mm) of the atmospheric pressure adjustment hole 6 is larger than the diameter of a conventional atmospheric pressure adjustment hole. More specifically, the pellicle for lithography of the present invention is mainly characterized in that the diameter D (mm) of the atmospheric pressure adjustment hole 6 is preferably at least 0.8 mm but no greater than 3.6 mm, and more preferably at least 1.0 mm but no greater than 3.0 mm. The diameter D of such an atmospheric pressure adjustment hole 6 is larger than 0.5 mm, which is the diameter of a conventional atmospheric pressure adjustment hole.

In this way, with regard to the pellicle for lithography of the present invention, due to the diameter D of the atmospheric pressure adjustment hole 6 being larger than conventional, it is possible to reduce foreign matter that either is generated via the atmospheric pressure adjustment hole 6 or might pass therethrough. The mechanism by which foreign matter is reduced by the atmospheric pressure adjustment hole 6 of the present invention, which has a larger diameter D than conventional, is explained in detail below.

In a case in which the pellicle is affixed to the exposure master plate, when the interior of the closed space is flushed with clean air or an inert gas or a difference in atmospheric pressure between the closed space and the exterior is relieved, gas passes through the atmospheric pressure adjustment hole to some extent. In this process, if foreign matter such as particles is present in the interior of the atmospheric pressure adjustment hole, the foreign matter might be fed into the interior of the closed space between the pellicle and the exposure master plate.

Conventionally also, in order to prevent such a problem due to foreign matter, the pellicle frame is subjected to various types of cleaning such as precision cleaning or blow cleaning using an air gun. Furthermore, an inner wall face of the pellicle frame is subjected to a resin coating using an inner wall pressure-sensitive adhesive, etc.

However, since the diameter of a conventional atmospheric pressure adjustment hole is as small as on the order of 0.5 mm, there have been cases in which a problem with cleaning or resin coating occurs.

For example, in the case of precision cleaning, when the pellicle frame is immersed in a cleaning liquid, if the diameter of the atmospheric pressure adjustment hole is small, gas might remain in the interior of the atmospheric pressure adjustment hole. As a result, ultrasonic cleaning might not be carried out sufficiently into the interior of the atmospheric pressure adjustment hole.

Furthermore, in the case of resin coating using an inner wall pressure-sensitive adhesive, etc., since the diameter of the atmospheric pressure adjustment hole is too small, a sufficient amount of coating liquid such as an inner wall pressure-sensitive adhesive might not reach the interior of the atmospheric pressure adjustment hole. As a result, an uncoated area that is not subjected to resin coating and has no inner wall pressure-sensitive adhesive layer formed thereon might remain on the inner wall face of the atmospheric pressure adjustment hole.

In contrast to the above, in the pellicle for lithography of the present invention, as described above the diameter D of the atmospheric pressure adjustment hole 6 is set so as to be larger than conventional. Because of this, cleaning such as ultrasonic cleaning can be carried out sufficiently up to the interior of the atmospheric pressure adjustment hole 6. Furthermore, a resin coating can be applied reliably without an uncoated area remaining on the inner wall face of the atmospheric pressure adjustment hole 6, and the inner wall pressure-sensitive adhesive layer 8b can be formed reliably on the inner wall face of the atmospheric pressure adjustment hole 6.

Specifically, in the case of the pellicle frame 3 where the diameter D of the atmospheric pressure adjustment hole 6 is set at 0.8 mm and the length (depth) L at 2 mm, when a plurality of the pellicle frames 3 that had been immersed in pure water were examined, it was confirmed that for all of the pellicle frames 3 there was no air remaining in the atmospheric pressure adjustment hole 6. This is clearly advantageous for carrying out sufficient cleaning compared with a case in which the diameter D of the atmospheric pressure adjustment hole 6 is set at 0.5 mm and the length L at 2 mm with air remaining being observed.

Furthermore, in the case of the pellicle frame 3 where the diameter D of the atmospheric pressure adjustment hole 6 is set at 0.8 mm and the length L at 2 mm, when coating of an inner wall face of the pellicle frame 3 and an inner wall face of the atmospheric pressure adjustment hole 6 was carried out by spraying using an inner wall pressure-sensitive adhesive, it was confirmed that coating was carried out reliably up to the inner wall face of the atmospheric pressure adjustment hole 6. More specifically, defining the thickness of the inner wall pressure-sensitive adhesive layer 8a by the inner wall pressure-sensitive adhesive on the inner wall face of the pellicle frame 3 as 1, when the diameter D is set at 0.5 mm, the thickness of the thinnest part of the inner wall pressure-sensitive adhesive layer 8b on the inner wall face of the atmospheric pressure adjustment hole 6 is no greater than 0.01. In contrast, when the diameter D is set at 0.8 mm, the thickness of the thinnest part of the inner wall pressure-sensitive adhesive layer 8b on the inner wall face of the atmospheric pressure adjustment hole 6 is increased to on the order of 0.2.

As hereinbefore described, in accordance with the present invention, sufficient cleaning and reliable resin coating can be carried out, and it is thus possible to reduce foreign matter that either is generated via the atmospheric pressure adjustment hole 6 or might pass therethrough.

Furthermore, in the pellicle for lithography of the present invention, since the diameter of the atmospheric pressure adjustment hole 6 is set larger than conventional, it is possible to decrease the speed of gas that passes through the atmospheric pressure adjustment hole 6 under atmospheric pressure variations.

The air flow rate through the atmospheric pressure adjustment hole 6 is limited by the filter 7 provided outside the atmospheric pressure adjustment hole 6. Because of this, when the diameter D of the atmospheric pressure adjustment hole 6, that is, the air flow cross-sectional area of the atmospheric pressure adjustment hole 6, increases, the speed of gas passing through the atmospheric pressure adjustment hole 6 decreases. When the air flow cross-sectional area of a case in which the diameter D of the atmospheric pressure adjustment hole 6 is 0.8 mm is compared with a case in which it is 0.5 mm, the air flow cross-sectional area of the former is at least 2.5 times the air flow cross-sectional area of the latter.

In this way, in accordance with the present invention, by decreasing the speed of gas passing through the atmospheric pressure adjustment hole 6 it is possible to reduce the risk of the occurrence of foreign matter that either is generated via the atmospheric pressure adjustment hole 6 or might pass therethrough.

As hereinbefore described, the larger the diameter D of the atmospheric pressure adjustment hole 6, the easier it is to ensure the cleanliness of the interior of the atmospheric pressure adjustment hole 6 in precision cleaning of the pellicle frame 3. Furthermore, the thickness of the inner wall pressure-sensitive adhesive layer 8b on the inner wall face of the atmospheric pressure adjustment hole 6 is easily ensured. Moreover, under atmospheric pressure variations, the speed of gas passing through the atmospheric pressure adjustment hole 6 decreases. As a result, the risk of the occurrence of foreign matter due to the atmospheric pressure adjustment hole 6 decreases.

However, it is preferable to form the atmospheric pressure adjustment hole 6 so that the strength of the pellicle frame 3 is not degraded. From the viewpoint of achieving a balance between reduction of foreign matter that either is generated via the atmospheric pressure adjustment hole 6 or might pass therethrough and ensuring of the strength of the pellicle frame 3, the diameter D (mm) of the atmospheric pressure adjustment hole 6 is preferably set to at least 0.8 mm but no greater than 3.6 mm, and more preferably at least 1.0 mm but no greater than 3.0 mm.

From the same viewpoint, the cross-sectional area S (mm²) of the atmospheric pressure adjustment hole 6 is preferably set to at least 0.5 mm² but no greater than 10.0 mm², more preferably at least 0.8 mm² but no greater than 8.0 mm², and yet more preferably at least 2.0 mm² but no greater than 5.0 mm².

Furthermore, since the height h of the pellicle frame 3 is limited, when the diameter D of the atmospheric pressure adjustment hole 6 is determined, it is preferable to take into consideration the viewpoint of ensuring the strength of the pellicle frame 3 and the structure of the filter 7 provided outside the atmospheric pressure adjustment hole 6. When the viewpoint of ensuring the strength and the structure of the filter 7 are taken into consideration, it is thought that the upper limit for the diameter D of the atmospheric pressure adjustment hole 6 is preferably a value obtained by subtracting on the order of 2 mm from the height h of the pellicle frame 3.

Furthermore, a proposal has recently been made to intentionally set a long overall length for the atmospheric pressure adjustment hole by inclining it or making it take an indirect route with respect to the thickness direction of the frame rather than machining the atmospheric pressure adjustment hole so that it is the shortest with respect to the thickness of the frame. However, it is thought that such an atmospheric pressure adjustment hole has no merit since not only do the cleaning properties or coating properties of the interior of the hole become poor, but it is also easy to cause unnecessary pressure loss when the atmospheric pressure is adjusted.

### EXAMPLES

The present invention is explained below more specifically by reference to Examples. A ‘mask’ in the Examples and Comparative Examples is illustrated as an example of the ‘exposure master plate’ and, needless to say, application to a reticle can be carried out in the same manner.

### Example 1

As a pellicle frame, a black-anodized duralumin-made frame was prepared so that the frame outer dimensions were 150 mm×122 mm×5.8 mm and the frame thickness was 2 mm. One atmospheric pressure adjustment hole was provided at the midpoint of a short side of the frame. The atmospheric pressure adjustment hole had a circular cross-sectional shape with a diameter of 0.8 mm and was machined so as to extend through the frame thickness of 2 mm.

After this frame was precision cleaned, the entire frame inner wall face was coated by spraying with a silicone pressure-sensitive adhesive (product name: KR3700) manufactured by Shin-Etsu Chemical Co., Ltd., thus forming an inner wall pressure-sensitive adhesive layer. Subsequently, a silicone pressure-sensitive adhesive for use in reticle fitting (product name: X40-3122) manufactured by Shin-Etsu Chemical Co., Ltd. was line-dispensed on a frame lower end face by a robot coating machine. Furthermore, a fluorine resin for pellicle film adhesion (product name: CYTOP CTX-109A) manufactured by Asahi Glass Co., Ltd. was line-dispensed on an upper end face on the opposite side by a robot and heated using a high-frequency induction heater.

Finally, a filter for atmospheric pressure adjustment (for dust prevention) was affixed so as to block the atmospheric pressure adjustment hole, thus completing the pellicle frame.

A pellicle film prepared in advance was adhered to the frame thus completed, thereby completing a pellicle.

The pellicle thus completed was adhered to a 12 inch silicon wafer, this was then stored in a pressure variation chamber, and an atmospheric pressure variation cycle of pressure reduction from normal pressure to 0.5 atm. and pressure recovery from 0.5 atm. to normal pressure was repeated five times. In this process, the pressure reduction from normal pressure to 0.5 atm. was carried out over 10 minutes in order to protect the pellicle film.

After the pressure variation cycle test was completed, when a foreign matter test was carried out for the inside area of the 12 inch silicon wafer that was protected by the pellicle, it was found that there was no increase in foreign matter.

Furthermore, after the foreign matter test was completed, the pellicle was peeled off from the silicon wafer, and the state of the inner wall pressure-sensitive adhesive layer coating with the silicone pressure-sensitive adhesive on the inner wall face of the atmospheric pressure adjustment hole was examined by splitting a portion of the frame where the atmospheric pressure adjustment hole was provided. At the same time, the state of the inner wall pressure-sensitive adhesive layer coating with the silicone pressure-sensitive adhesive on the frame inner wall face was examined. From the results, it was found that the thickness of the inner wall pressure-sensitive adhesive layer on the inner wall face of the atmospheric pressure adjustment hole was 2 to 3 μm, whereas the thickness of the inner wall pressure-sensitive adhesive layer on the frame inner wall face was on the order of 10 μm.

### Example 2

A pellicle was completed in the same manner as in Example 1 except that an atmospheric pressure adjustment hole was machined so as to have a circular cross-sectional shape with a diameter of 3.0 mm, and the pellicle thus completed was affixed to a 12 inch silicon wafer.

Subsequently, in the same manner as in Example 1, after an atmospheric pressure variation cycle test was carried out, a foreign matter test and examination of the state of the inner wall pressure-sensitive adhesive layer coating were carried out in sequence.

From the results of the foreign matter test, in Example 2 also, as in Example 1, no increase in foreign matter was observed in the inside area of the 12 inch silicon wafer that was protected by the pellicle.

Furthermore, from the results of examining the state of the inner wall pressure-sensitive adhesive layer coating, in Example 2 it was found that the thickness of the inner wall pressure-sensitive adhesive layer on the inner wall face of the atmospheric pressure adjustment hole was 3 to 5 μm, whereas the thickness of the inner wall pressure-sensitive adhesive layer on the frame inner wall face was on the order of 10 μm.

### Comparative Example 1

A pellicle was completed in the same manner as in Example 1 except that an atmospheric pressure adjustment hole was machined so as to have a circular cross-sectional shape with a diameter of 0.5 mm, and the pellicle thus completed was affixed to a 12 inch silicon wafer.

Subsequently, in the same manner as in Example 1, after an atmospheric pressure variation cycle test was carried out, a foreign matter test and examination of the state of the inner wall pressure-sensitive adhesive layer coating were carried out in sequence.

From the results of the foreign matter test, in Comparative Example 1, two pieces of foreign matter were observed around the atmospheric pressure adjustment hole in the inside area of the 12 inch silicon wafer that was protected by the pellicle.

Furthermore, from the results of examining the state of the inner wall pressure-sensitive adhesive layer coating, in Comparative Example 1 it was found that the thickness of the inner wall pressure-sensitive adhesive layer on the inner wall face of the atmospheric pressure adjustment hole was 0.02 to 0.05 μm, whereas the thickness of the inner wall pressure-sensitive adhesive layer on the frame inner wall face was on the order of 10 μm.

### Comparative Example 2

A pellicle was completed in the same manner as in Example 1 except that an atmospheric pressure adjustment hole was machined so as to have a circular cross-sectional shape with a diameter of 4.0 mm, and the pellicle thus completed was affixed to a 12 inch silicon wafer.

In Comparative Example 2, when an attempt was made to cover the atmospheric pressure adjustment hole with a diameter of 4.0 mm by a filter prepared so as not to protrude from the 5.8 mm height of the frame, the width of affixing for the pressure-sensitive adhesive outside the filter-affixing area became less than 1 mm, thus degrading the reliability.

Furthermore, since the atmospheric pressure adjustment hole with a diameter of 4.0 mm was opened relative to the height of 5.8 mm of the frame, there was a possibility of a problem with frame strength occurring.

Subsequently, in the same manner as in Example 1, after an atmospheric pressure variation cycle test was carried out, a foreign matter test and examination of the state of the inner wall pressure-sensitive adhesive layer coating were carried out in sequence.

From the results of the foreign matter test, in Comparative Example 2, no increase in foreign matter was observed in the inside area of the 12 inch silicon wafer that was protected by the pellicle.

Furthermore, from the results of examining the state of the inner wall pressure-sensitive adhesive layer coating, in Comparative Example 2 it was found that the thickness of the inner wall pressure-sensitive adhesive layer on the inner wall face of the atmospheric pressure adjustment hole was 4 to 6 μm, whereas the thickness of the inner wall pressure-sensitive adhesive layer on the frame inner wall face was on the order of 10 μm.

In the above, a pellicle frame having a height of 5.8 mm was used, but in the case of pellicle frames having heights of 4.5 mm and 3.0 mm, it can be predicted that the upper limit for the diameter of the atmospheric pressure adjustment hole would be on the order of 2.5 mm and 1.0 mm respectively.

What is claimed is:

1. A pellicle for lithography comprising:
a pellicle frame provided with an atmospheric pressure adjustment hole that extends through from an outer peripheral face to an inner peripheral face,
a ratio S/L of a cross-sectional area S (mm²) of a cross-section that is perpendicular to the depth direction of the atmospheric pressure adjustment hole relative to a length L (mm) in the depth direction of the atmospheric pressure adjustment hole being at least 0.25 mm but no greater than 5.0 mm.

2. The pellicle for lithography according to claim 1, wherein the cross-sectional area S is at least 0.5 mm² but no greater than 10.0 mm².

3. The pellicle for lithography according to claim 1, wherein the cross-sectional area S is at least 0.8 mm² but no greater than 8.0 mm².

4. The pellicle for lithography according to claim 1, wherein the atmospheric pressure adjustment hole has a diameter of at least 0.8 mm but no greater than 3.6 mm.

5. The pellicle for lithography according to claim 1, wherein the atmospheric pressure adjustment hole has a diameter of at least 1.0 mm but no greater than 3.0 mm.

6. The pellicle for lithography according to claim 1, wherein the difference between the height of the pellicle frame and the diameter of the atmospheric pressure adjustment hole satisfies the expression below
2mm≦(h−D)≦5mm
(here, h denotes a height (mm) of the pellicle frame and D denotes a diameter (mm) of the atmospheric pressure adjustment hole).

7. The pellicle for lithography according to claim 1, wherein the atmospheric pressure adjustment hole has a circular cross-sectional shape.

8. The pellicle for lithography according to claim 1, wherein the atmospheric pressure adjustment hole comprises on an inner wall face an inner wall pressure-sensitive adhesive layer.

9. The pellicle for lithography according to claim 1, wherein the pellicle frame comprises on an inner wall face an inner wall pressure-sensitive adhesion layer.

10. The pellicle for lithography according to claim 8, wherein the inner wall pressure-sensitive adhesion layer is formed from a silicone pressure-sensitive adhesive or an acrylic pressure-sensitive adhesive.

11. The pellicle for lithography according to claim 9, wherein the inner wall pressure-sensitive adhesion layer is formed from a silicone pressure-sensitive adhesive or an acrylic pressure-sensitive adhesive.

12. The pellicle for lithography according to claim 1, wherein the atmospheric pressure adjustment hole is provided with a dust filter.
